(19) United States
(12) Patent Application Publication
(10) Pub. No.: US 2008/0157297 A1
(43) Pub. Date: Jul. 3, 2008

(54) Stress-Resistant Leadframe and Method

(76) Inventor: Takahiko Kudoh, Beppu (JP)

Correspondence Address: TEXAS INSTRUMENTS INCORPORATED, P O BOX 655474, M/S 3999, DALLAS, TX, 75265, US

(21) Appl. No.: 11/618,275

(22) Filed: Dec. 29, 2006

(51) Int. Cl. H01L 23/495; H01L 21/00

(52) U.S. Cl. 257/666

(57) ABSTRACT

Leadframes resistant to stress and semiconductor devices incorporating such leadframes are described, including but not limited to QFN packages and the like. According to preferred embodiments disclosed herein, a stress-resistant leadframe for a semiconductor device includes a paddle for receiving a semiconductor chip. The paddle is supported with tie bars extending between the paddle and leadframe edge. One or more flexion bar included within the span of at least one of the tie bars is configured to alleviate mechanical stresses potentially encountered by the leadframe.

### TECHNICAL FIELD

The invention relates to electronic semiconductor devices and manufacturing. More particularly, the invention relates to leadframes for microelectronic semiconductor devices and methods for implementing leadframes having resistance to the application of thermal and mechanical stress.

### BACKGROUND OF THE INVENTION

A leadframe is, in the mechanical sense, literally the “frame” of a packaged semiconductor device. Among other functions, the leadframe provides structural mechanical support to a semiconductor chip during its assembly into a packaged product. Leadframes common in the art typically consist of a paddle, sometimes called a die paddle, to which the chip is attached. Leads radiating out from the paddle serve as the means by which the chip may be electrically connected to the outside world. The chip is connected to the leads by wires through wirebonding. Generally, for both mechanical and electrical reasons, a gap is required between the leads and the paddle. Since this requirement rules out any connection between the paddle and the leads, it becomes necessary to use another approach in order to maintain a connection between the paddle and the rest of the leadframe. In typical packages, tie bars extend from the four corners of the paddle outward toward the outer corners of the package, thus establishing a mechanical framework to support the paddle.

Leadframes are manufactured by a highly automated process that employs stamping and punching steps and masking and chemical etching steps to progressively form the intended leadframe structure. In the process of incorporating a finished leadframe into a semiconductor device package, usually after a chip is attached to the paddle, taping is sometimes used to support and hold the relatively delicate leadframe in place during other manufacturing steps such as wirebonding and molding. Taping consists of putting a tape over one side of the leadframe to prevent deformation. Typically, tape is applied to the back of the leadframe prior to molding the package, and is removed after molding.

Wirebonding typically uses heat and ultrasonic vibration to form a bond between a wire and a bond pad. The use of taping techniques can be beneficial in terms of an efficient package assembly process. However, since the adhesive tape is attached to one of the surfaces of the leadframe, a problem sometimes occurs due to the application of heat. The leadframe may be warped due to a difference in the coefficient of thermal expansion (CTE) between the leadframe material, usually metal, and the tape, usually polyimide, organic polymer, or similar material. Warpage is detrimental to further steps in package assembly and may also ultimately cause decreased reliability in the completed semiconductor devices. Another, more immediate problem, is that the tape may have a tendency to peel away from the leadframe due to the thermal mismatch under the application of heat, and perhaps assisted by ultrasonic vibrations, interfering with the completion of wirebonding.

Following the attachment of a chip to the front surface of a leadframe and the completion of wirebonds, it is conventional to encapsulate the chip in plastic or resin mold compound. This is carried out by placing the leadframe within a mold. Liquid mold compound is introduced into the mold so that the chip becomes encased in it. The mold compound then cures, forming a protective covering. It is preferred to prevent the mold compound from contaminating the back surface of the leadframe, that is, the surface facing away from the chip, since mold compound on the back surface may inhibit the escape of heat generated within the completed package. This prevention of the travel of mold compound to the back of the leadframe is another function of taping. Of course, any tendency of the tape to peel due to CTE differences aggravated by the heat of wirebonding and/or encapsulation, has the potential to cause further problems associated with leaking mold compound.

In view of the problems encountered in the current practice of the semiconductor manufacturing art, improved leadframe designs and techniques better able to withstand stress and reduce deformation induced by differences in thermal expansion characteristics, e.g., CTE, among materials used in manufacturing semiconductor device packages would be useful and advantageous.

### SUMMARY OF THE INVENTION

In carrying out the principles of the present invention, in accordance with preferred embodiments thereof, novel stress-resistant features are incorporated into leadframes for semiconductor devices. The detailed description set forth below, and the appended drawings, are intended to provide a description of the presently preferred embodiment of the invention, and are not intended to represent the only forms in which the invention may be practiced. It should be understood that the same or equivalent functions may be accomplished by different embodiments that are intended to be encompassed within the principles and scope of the invention. As will be understood by those of skill in the applicable arts, the invention may be applied to various packages and package types, but may be particularly useful in the context of Quad Flat No-lead (QFN) and similar packaging.

According to one aspect of the invention, preferred embodiments of a leadframe for a semiconductor device include a paddle for receiving a semiconductor chip. Tie bars support the paddle, extending from one end at the paddle to another end at the edge of the leadframe. One or more flexion bars for alleviating mechanical stress are included between the ends of at least one of the tie bars.

According to another aspect of the invention, a representative embodiment of a stress-relieving leadframe includes a tie bar having an integral flexion bar in a configuration which includes a series of supplementary angles.

According to another aspect of the invention, a representative embodiment of a stress-relieving leadframe includes a tie bar having an integral flexion bar in a configuration which includes a series of supplementary curves.

According to yet another aspect of the invention, a preferred method for making a leadframe for a use in a semiconductor device package includes steps for forming a paddle for receiving a semiconductor chip. A number of tie bars support the paddle, with one end of a tie bar terminating at the paddle, and the other end of a tie bar terminating at an edge of the leadframe. Steps are also included by which at least one flexion bar is formed between the ends of at least one of the tie bars.

According to another aspect of the invention, preferred methods for manufacturing a stress-resistant leadframe include the step of forming a flexion bar configured arranged in a series of supplementary angles within the span of a tie bar supporting a paddle.

According to still another aspect of the invention, preferred methods for manufacturing a stress-resistant leadframe include the step of forming a flexion bar configured arranged in a series of supplementary curves within the span of a tie bar supporting a paddle.

According to another aspect of the invention, a preferred embodiment includes a method for assembling a semiconductor device package using a stress-resistant leadframe. Steps include providing a leadframe having a paddle supported by a plurality of tie bars, at least one tie bar being endowed with at least one flexion bar. One or more taping, chip attach, wirebonding, or encapsulation steps benefit from the action of the flexion bar.

The invention has numerous advantages including but not limited to providing methods and devices offering one or more of the following; improvements in leadframe durability, improvements in device assembly process efficiency, and reduced cost. These and other features, advantages, and benefits of the present invention can be understood by one of ordinary skill in the arts upon careful consideration of the detailed description of representative embodiments of the invention in connection with the accompanying drawings.

### BRIEF DESCRIPTION OF THE DRAWINGS

The present invention will be more clearly understood from consideration of the following detailed description and drawings in which:

FIG. 1 is a top view of an example of preferred embodiments of stress-resistant leadframes and method of the invention;

FIG. 2 is a partial top view of an example of an alternative preferred embodiment of a stress-resistant leadframe according to the invention;

FIG. 3 is a partial top view of an example of an alternative preferred embodiment of a stress-resistant leadframe according to the invention; and

FIG. 4 is a partial top view of an example of an alternative preferred embodiment of a stress-resistant leadframe according to the invention.

References in the detailed description correspond to like references in the Figures unless otherwise noted. Descriptive and directional terms used in the written description such as first, second, top, bottom, upper, side, etc., refer to the drawing as laid out on the paper and not to physical limitations of the invention unless specifically noted. The drawings are not to scale, and some features of embodiments shown and discussed are simplified or amplified for illustrating the principles, features, and advantages of the invention.

### DETAILED DESCRIPTION OF PREFERRED EMBODIMENTS

In general, the invention provides leadframes with improved resistance to mechanical stress. As shown and described herein, preferred embodiments of the invention provide a leadframe adapted to absorb stress produced by thermal expansion and contraction.

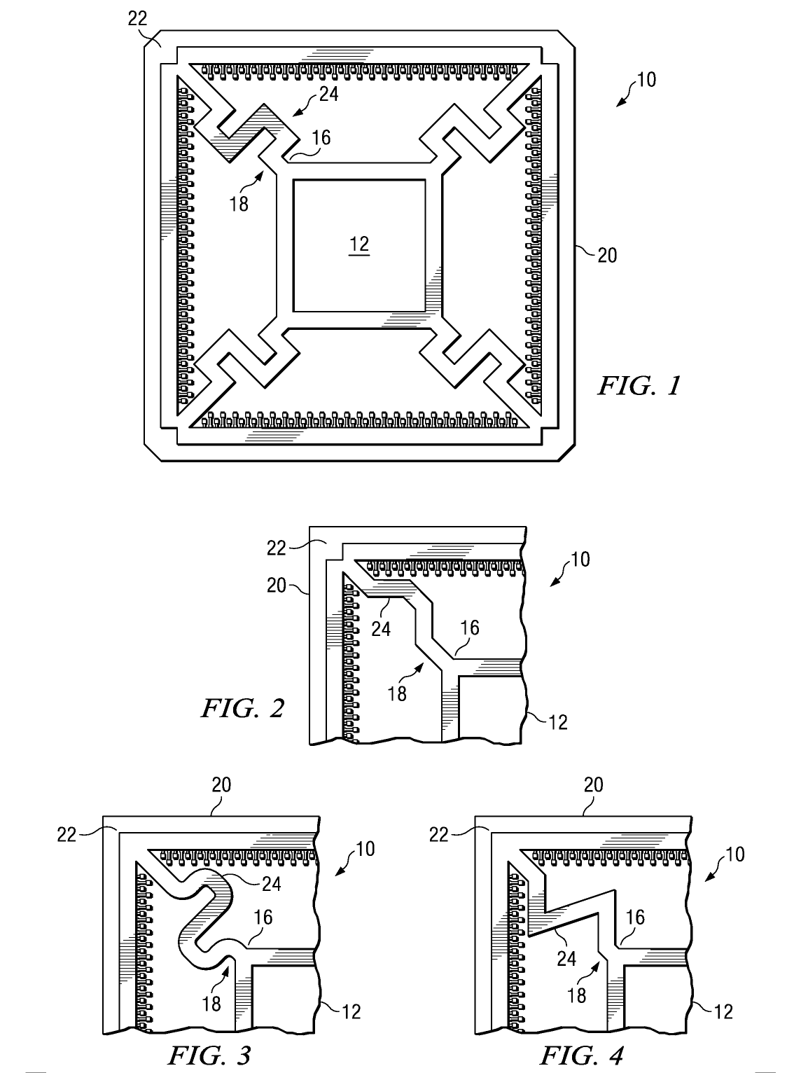

Referring to the drawings, a top view in FIG. 1, and partial top views in FIGS. 2 through 4, depict examples of preferred embodiments of stress-resistant leadframes 10 and methods of the invention. A generally rectangular leadframe 10 is shown, with a paddle 12 for receiving a semiconductor chip (not shown). The paddle 12 is supported, preferably from the corners 16, by tie bars 18 spanning from the paddle 12 to the outer periphery 20 of the leadframe 10, again, preferably the corners 22. One or more, preferably all, of the tie bars 18 have one or more flexion bar 24 located between the leadframe edge 20 and paddle 12. To provide maximum benefit, it is preferred to have a flexion bar 24 in each of the tie bars 18, although variations are possible within the scope of the invention depending upon application requirements and manufacturing considerations. As shown in the Figures, various shapes of flexion bar 24 are possible as long as the flexion bar shape(s) used in a particular implementation of the invention are sufficient to alleviate tensile stress exerted by thermal changes in the leadframe environment. Preferably, the flexion bars are formed as integral parts of the tie bars during the leadframe manufacturing process. It is contemplated the invention has the advantage of making use of known leadframe manufacturing processes in the manufacture of the improved leadframes having stress-resistant features.

Due to the area constraints imposed by leadframe geometry, it is preferable that the tie bars used in a leadframe connect two opposing points without making contact elsewhere. Thus, the flexion bars preferably depart from the path established by the tie bar at one end, deviate somewhat, and return to the same path at the opposite end. As shown in FIGS. 1, 2, and 4, the flexion bars preferably contain “supplementary angles”, meaning for the purposes of this description; any number of angles, the sum of which is about 180 degrees, or approximately a multiple of 180 degrees. The term as used herein is not restricted to mean the sum of two angles whose sum is exactly 180 degrees as may sometimes be used in the study of geometry. For example, six 90 degree angles, or one 90 degree angle in combination with two 45 degree angles, are supplementary angles within the scope of the invention. Additionally, the term “supplementary curves” is coined herein, referring to any number of curves, or arcs, whose sum is approximately a multiple of 180 degrees, as illustrated in the exemplary embodiment of FIG. 3. It should also be noted that the number and location of the tie bars is not intended to be restricted by the examples herein. The invention may be practiced with various numbers of flexion bars included in various numbers of tie bars at various locations depending upon the particular requirements of the implementation at hand. For example, in some instances it may be desirable to use 3 or 5, or 6 tie bars, or to connect tie bars from the sides of the paddle or leadframe instead of or in addition to the corners.

Those of ordinary skill and knowledge in the semiconductor device manufacturing arts will appreciate that the stress-resistant leadframe may be used in the assembly of semiconductor device packages by adapting common manufacturing processes. When providing a leadframe having a paddle, which is usually done in any case, at least one tie bar supporting the paddle is endowed with at least one expansion bar. Other steps ordinarily taken in the package manufacturing process may preferably also be used. These may include attaching one or more chips to the paddle and wirebonding electrical connections between the chip and the leadframe. The practice of the invention is particularly beneficial in processes that include taping the back side of the leadframe preparatory to wirebonding or encapsulation. Of course, the invention may be practiced in any device assembly process in which thermal or mechanical stress is of concern. For example, the invention may be practiced in taped and non-taped QFN assembly processes. The flexion bar provides protection to the integrity of the leadframe and operable electrical connections between the leadframe and chip by providing a path for stresses, particularly those induced by thermal mismatch of materials. The flexion bar safely alleviates such stresses, preferably directing them away from more delicate and often vital portions of the package.

The invention provides advantages including but not limited to reduction in damage to device package components due to thermal stress, and to increased efficiency in IC package assembly, and reduced costs. While the invention has been described with reference to certain illustrative embodiments, the methods and systems described are not intended to be construed in a limiting sense. Various modifications and combinations of the illustrative embodiments as well as other advantages and embodiments of the invention will be apparent to persons skilled in the arts upon reference to the description and claims.

I claim:

1. A leadframe for a semiconductor device comprising:
a paddle for receiving a semiconductor chip;
a plurality of tie bars supporting the paddle, wherein one end of a tie bar terminates at the paddle, and the other end of a tie bar terminates at the edge of the leadframe; and
at least one flexion bar included between the ends of at least one of the tie bars.

2. A leadframe according to claim 1 wherein the plurality of tie bars further comprises three tie bars.

3. A leadframe according to claim 1 wherein the plurality of tie bars further comprise four tie bars.

4. A leadframe according to claim 1 wherein the plurality of tie bars further comprise four tie bars, and wherein the four tie bars span from the four corners of a rectangular paddle to the four corners of a rectangular leadframe.

5. A leadframe according to claim 1 wherein at least one flexion bar further comprises a configuration of tie bar material arranged in a series of supplementary angles.

6. A leadframe according to claim 1 wherein at least one flexion bar further comprises a configuration of tie bar material arranged in a series of right angles.

7. A leadframe according to claim 1 wherein at least one flexion bar further comprises a configuration of tie bar material arranged in a series of supplementary curves.

8. A leadframe according to claim 1 further comprising a QFN package leadframe.

9. A method for making a leadframe for a use in a semiconductor device package comprising the steps of:
forming a paddle for receiving a semiconductor chip;
forming a plurality of tie bars supporting the paddle, wherein one end of a tie bar terminates at the paddle, and the other end of a tie bar terminates at the edge of the leadframe; and
forming at least one flexion bar between the ends of at least one of the tie bars.

10. A method according to claim 9 wherein the step of forming a plurality of tie bars further comprises forming at least three tie bars.

11. A method according to claim 9 wherein the step of forming a plurality of tie bars further comprises forming four tie bars spanning from the four corners of a rectangular paddle to the four corners of a rectangular leadframe.

12. A method according to claim 9 wherein the step of forming at least one expansion bar further comprises a step of forming a flexion bar configured of tie bar material arranged in a series of supplementary angles.

13. A method according to claim 9 wherein the step of forming at least one flexion bar further comprises a step of forming a flexion bar configured of tie bar material arranged in a series of right angles.

14. A method according to claim 9 wherein the step of forming at least one expansion bar further comprises a step of forming a flexion bar configured of tie bar material arranged in a series of supplementary curves.

15. A method for assembling a semiconductor device package comprising the steps of:
providing a leadframe having a paddle supported by a plurality of tie bars, wherein at least one tie bar is endowed with at least one flexion bar;
attaching one or more chip to the paddle;
wirebonding electrical connections between the chip and the leadframe; and
encapsulating the leadframe, bondwires, and the one or more chip in a dielectric package.

16. A method according to claim 15 wherein plurality of tie bars are formed to span from four corners of a rectangular paddle to four corners of a rectangular leadframe.

17. A method according to claim 15 wherein at least one flexion bar is formed of tie bar material arranged in a series of supplementary angles.

18. A method according to claim 15 wherein at least one flexion bar is formed of tie bar material arranged in a series of right angles.

19. A method according to claim 15 wherein at least one flexion bar is formed of tie bar material arranged in a series of supplementary curves.

20. A method according to claim 15 wherein the semiconductor device package further comprises a QFN package.
